(19) United States
(12) Patent Application Publication
(10) Pub. No.: US 2022/0112962 A1
(43) Pub. Date: Apr. 14, 2022

(54) ENCLOSURE VENT ASSEMBLY

(71) Applicant: Donaldson Company, Inc., Minneapolis, MN (US)

(72) Inventors: Daniel J. Dotzler, Webster, MN (US); James P. Moorman, Eden Prairie, MN (US); Aflal Rahmathullah, Savage, MN (US); Koen L. R. Vanderbeke, Linden (BE)

(21) Appl. No.: 17/498,465

(22) Filed: Oct. 11, 2021

Related U.S. Application Data
(60) Provisional application No. 63/090,505, filed on Oct. 12, 2020.

(51) Int. Cl. F16K 24/04; F16K 17/40; F16K 15/14; F16K 27/02

(52) U.S. Cl. CPC F16K 24/04; F16K 27/0209; F16K 15/148; F16K 13/04

(57) ABSTRACT

The technology disclosed herein relates to, at least in part, an enclosure vent assembly. A vent body defines a vent cavity, a first axial end, a second axial end, circumferential threads positioned towards the second axial end, and a sealing surface. The sealing surface surrounds the vent cavity and faces the second axial end. A vent is disposed in the vent body, wherein the vent extends across the vent cavity. A vent mount defines a mount opening, mating threads configured to releasably engage the circumferential threads, a facing surface about the mount opening configured to oppose the sealing surface, and a fastening feature. The fastening feature is configured to rotatably fix the vent mount to a housing.

### CROSS REFERENCE TO RELATED APPLICATIONS

This application claims the benefit of U.S. Provisional Application No. 63/090,505, filed 12 Oct. 2020, the disclosure of which is incorporated by reference herein in its entirety.

### TECHNOLOGICAL FIELD

The present disclosure is generally related to a vent assembly. More particularly, the present disclosure is related to a vent assembly for an enclosure.

### BACKGROUND

Protective vents are typically employed to allow pressure equalization between a housing and the environment outside of the housing. Vents can use a water, dust, and oil resistant membrane to allow gas pressures to equalize while preventing liquid and solid contaminants from passing through into the housing. The vents generally form a seal with the housing so that air is directed through the vent for pressure equalization. However, the wall thicknesses of the housings are not consistent, so different vent configurations may be necessary to form a seal with walls having different wall thicknesses. Furthermore, housing walls that are particularly thin may pose a challenge for creating a seal with a vent due to the decreased rigidity associated with some materials used to construct a particularly thin housing wall.

### SUMMARY

The vent assembly consistent with the technology disclosed herein is generally configured to form a seal with housing walls across various wall thicknesses. In some embodiments the vent assembly consistent with the technology disclosed herein is configured to form a seal with relatively thin walls.

The technology disclosed herein relates to, at least in part, an enclosure vent assembly. A vent body defines a vent cavity, a first axial end, a second axial end, circumferential threads positioned towards the second axial end, and a sealing surface. The sealing surface surrounds the vent cavity and faces the second axial end. A vent is disposed in the vent body, wherein the vent extends across the vent cavity. A vent mount defines a mount opening, mating threads configured to releasably engage the circumferential threads, a facing surface about the mount opening configured to oppose the sealing surface, and a fastening feature. The fastening feature is configured to rotatably fix the vent mount to a housing.

In some such embodiments, the vent mount is an anchor nut. Additionally or alternatively, the fastening feature has a snap fit cantilever. Additionally or alternatively, the snap fit cantilever is positioned radially outward from the mount opening. Additionally or alternatively, the vent body defines an annular pocket about the vent cavity that extends in the axial direction and is configured to receive the snap fit cantilever. Additionally or alternatively, the fastening feature is one of rivets and screws. Additionally or alternatively, the sealing surface and the facing surface are configured to apply axial compression to the housing. Additionally or alternatively, the vent mount is configured to be axially translatable relative to the housing. Additionally or alternatively, the vent is a passive airflow vent. Additionally or alternatively, the vent is a relief valve.

Some embodiments of the present technology relate to a vented housing. A housing defines an enclosure and a housing opening in communication with the enclosure. A vent mount has a fastening feature that is rotatably fixed to the housing about the housing opening within the enclosure. An enclosure vent has a vent body defining a vent cavity and a vent. The vent is disposed in the vent body across the vent cavity. The vent mount releasably engages the vent body.

In some such embodiments, the vent mount and the enclosure vent are configured to apply axial compression to the housing about the housing opening. Additionally or alternatively, the vent mount is an anchor nut. Additionally or alternatively, the fastening feature is a snap fit cantilever. Additionally or alternatively, the vent mount defines a mount opening and the snap fit cantilever is positioned radially outward from the mount opening. Additionally or alternatively, the vent body defines an annular pocket around the vent cavity that extends in an axial direction and is configured to receive the snap fit cantilever. Additionally or alternatively, the fastening feature has one of rivets and screws. Additionally or alternatively, the enclosure vent defines a sealing surface around the vent cavity and the vent mount defines a facing surface around the vent cavity, and wherein the facing surface and the sealing surface are configured to apply axial compression to the housing. Additionally or alternatively, the vent is a passive airflow vent. Additionally or alternatively, the vent is a relief valve.

Some embodiments of the present technology relate to a vent assembly. A vent body defines a vent cavity, a first axial end and a second axial end. Circumferential threads are positioned towards the second axial end. A sealing surface surrounds the vent cavity and faces the second axial end, and an annular pocket is defined about the vent cavity having a depth in the axial direction. A vent is disposed in the vent body, where the vent extends across the vent cavity.

In some such embodiments, the vent has a PTFE membrane. Additionally or alternatively, the vent is a passive airflow vent. In some such embodiments, the vent assembly has a relief valve in parallel with the passive airflow vent with respect to airflow through the vent body. In some such embodiments, the relief valve is an umbrella valve defining a vent opening and a vent mounting surface about the vent opening, and the passive airflow vent is coupled to the vent mounting surface across the vent opening. In some such embodiments, the passive airflow vent is recessed in the axial direction from an outer portion of the relief valve.

Additionally or alternatively, the vent is a relief valve. Additionally or alternatively, the annular pocket is positioned radially between the circumferential threads and the sealing surface. Additionally or alternatively, the annular pocket extends axially from the sealing surface towards the first axial end. Additionally or alternatively, the annular pocket has an axial depth ranging from 2 mm to 20 mm. Additionally or alternatively, the annular pocket has a width ranging from 4 mm to 15 mm. Additionally or alternatively, the vent has a vent cover extending across the first axial end of the vent body. Additionally or alternatively, the vent cover has a puncturing mechanism extending from the cover towards the vent.

Some embodiments of the present technology relate to a vent assembly. A housing insertion portion is configured to be inserted through an opening in a housing. The housing insertion portion has a cylindrical component having an axial length along a central axis. Four axial protrusions are configured to be disposed around the cylindrical component, where each of the four axial protrusions extend in the axial direction and are configured to be positioned radially outward from the cylindrical component. The four axial protrusions are spaced 80° to 100° apart relative to the central axis. A sealing surface surrounds the cylindrical component. The sealing surface is configured to surround the four axial protrusions. In some such embodiments, the four axial protrusions are spaced 90° apart. Additionally or alternatively, each axial protrusion has an axial length ranging from 1 mm to 10 mm. Additionally or alternatively, each axial protrusion has a width ranging from 3 mm to 15 mm. Additionally or alternatively, a vent is coupled to the housing insertion portion. Additionally or alternatively, the vent is a passive airflow vent. In some such embodiments, a relief valve is in parallel with the passive airflow vent with respect to airflow through the vent body. In some such embodiments, the relief valve is an umbrella valve defining a vent opening and a vent mounting surface about the vent opening, and the passive airflow vent is coupled to the vent mounting surface across the vent opening. In some such embodiments, the passive airflow vent is recessed in the axial direction from an outer portion of the relief valve.

Additionally or alternatively, the vent is a relief valve. Additionally or alternatively, the vent assembly has a facing surface that is configured to oppose the sealing surface, where the facing surface is positioned radially outward from the axial protrusions. Additionally or alternatively, two of the axial protrusions comprise snap fit cantilevers.

The above summary is not intended to describe each embodiment or every implementation. Rather, a more complete understanding of illustrative embodiments will become apparent and appreciated by reference to the following Detailed Description of Exemplary Embodiments and claims in view of the accompanying figures of the drawing.

### BRIEF DESCRIPTION OF THE DRAWINGS

The present technology may be more completely understood and appreciated in consideration of the following detailed description of various embodiments in connection with the accompanying drawings.

FIG. 1 is a perspective view of an example vent assembly consistent with various embodiments.

FIG. 2A is an example cross-sectional view of a first example implementation vent assembly consistent with FIG. 1.

FIG. 2B is an example cross-sectional view of a second example implementation of the vent assembly consistent with FIG. 1.

FIG. 3 is an example exploded view of the example vent assembly of FIG. 2A.

FIG. 4 is an example vent mount mounted to a housing, consistent with some embodiments.

FIG. 5 is a perspective view of an example vent consistent with some embodiments.

FIG. 6 is a cross-sectional view of another example vent consistent with the technology disclosed herein.

FIG. 7 is a cross-sectional view of yet another example vent consistent with the technology disclosed herein.

FIG. 8 is a cross-sectional view of yet another example vent consistent with the technology disclosed herein.

FIG. 9 is a cross-sectional view of yet another example vent assembly consistent with the technology disclosed herein.

The figures are rendered primarily for clarity and, as a result, are not necessarily drawn to scale. Moreover, various structure/components, including but not limited to fasteners, electrical components (wiring, cables, etc.), and the like, may be shown diagrammatically or removed from some or all of the views to better illustrate aspects of the depicted embodiments, or where inclusion of such structure/components is not necessary to an understanding of the various exemplary embodiments described herein. The lack of illustration/description of such structure/components in a particular figure is, however, not to be interpreted as limiting the scope of the various embodiments in any way.

### DETAILED DESCRIPTION

The vent assembly consistent with the technology disclosed herein is generally configured to form a seal with housing walls across various wall thicknesses. In some embodiments the vent assembly consistent with the technology disclosed herein is configured to form a seal with relatively thin walls.

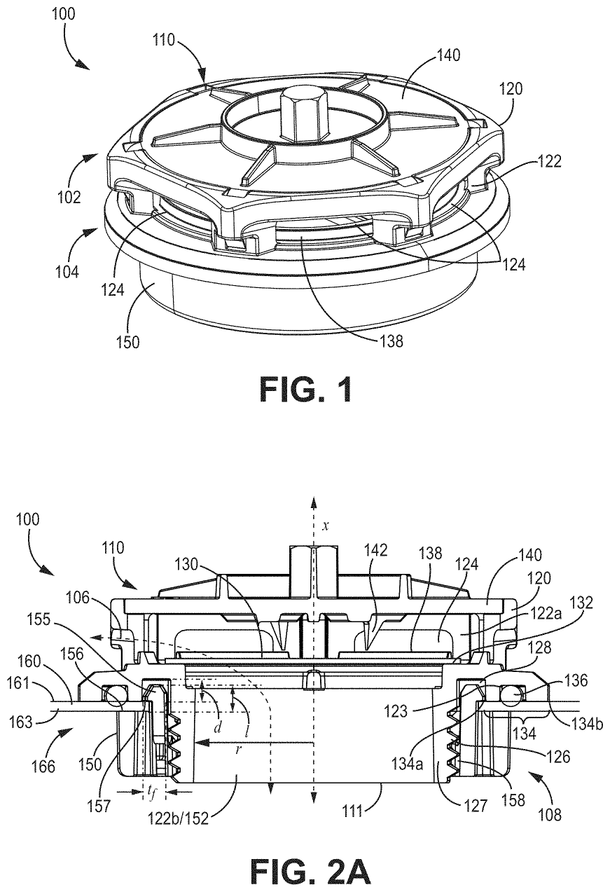

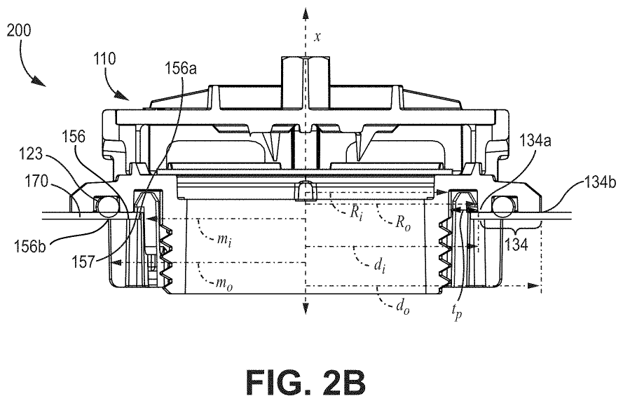

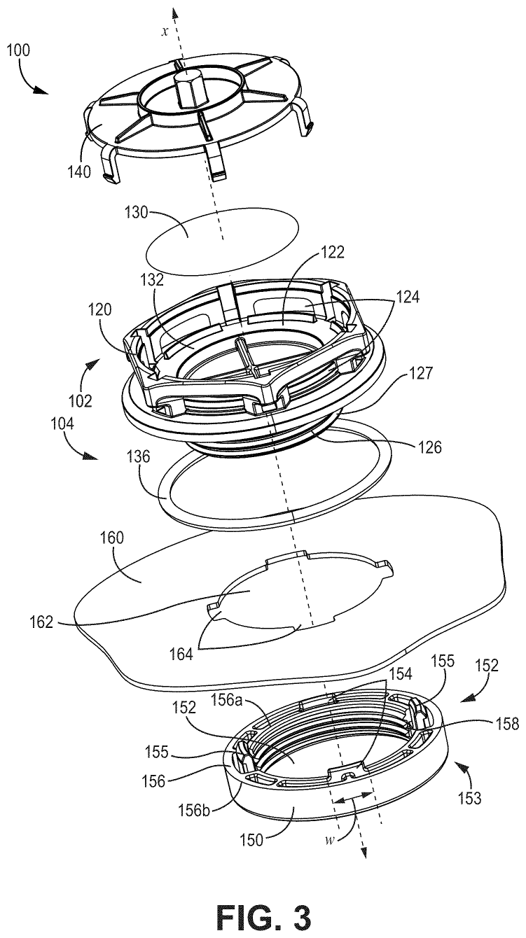

FIG. 1 is an example vent assembly 110 consistent with various embodiments. FIG. 2A depicts a cross-sectional view of an example implementation of a vented housing 100 that incorporates a vent assembly 110 generally consistent with FIG. 1, and FIG. 3 depicts an exploded perspective view of an example implementation of a vented housing 100 consistent with FIG. 2A. FIG. 2B depicts a cross-sectional view of another example implementation of a vented housing 200 incorporating the vent assembly 110 of FIG. 1.

The vented housing 100 has a vent assembly 110 coupled to a housing 160 and, as such, the vent assembly 110 is shown in relationship with the housing 160, although the housing 160 is generally not a component of the vent assembly 110. The housing 160 defines an enclosure 166 that is configured to house system components such as electronic components and battery cells, as examples. The vent assembly 110 is configured to accommodate gas flow in to and out of the housing 160 while obstructing the passage of particles and liquids (such as water).

The vent assembly 110 has a vent 130 and a coupling structure 108. The vent 130 is generally positioned in fluid communication with a housing opening 162 of the housing 160. The vent assembly 110 is generally configured to define an airflow pathway 106 (visible in FIG. 2A) between the enclosure 166 and the environment outside of the housing 160 through a vent 130. The vent 130 is configured to allow passive airflow into and out of the housing 160 from the environment outside of the housing 160 by flowing through the vent 130. In some embodiments, the vent 130 is configured to prevent particles from entering the housing 160. In some embodiments, the vent 130 is also configured to prevent liquids from entering the housing 160.

As is visible in FIG. 2A, the airflow pathway 106 of the vent assembly 110 is configured to extend between an enclosure opening 111 defined by the vent assembly 110 towards the second axial end 104 and an environmental opening 124 defined by the vent assembly 110 towards the first axial end 102. The enclosure opening 111 is configured to be in direct fluid communication with the enclosure 166. The environmental opening 124 is configured to be in direct fluid communication with the environment outside of the housing 160. The environmental opening 124 is a series of discrete openings defined around the vent body 120 and around a central axis x of the vent body 120. The series of discrete openings surround the vent 130.

The vent 130 can be constructed of a variety of different materials and combinations of materials. In some embodiments the vent 130 is a breathing vent, meaning that the vent 130 is configured to passively allow airflow therethrough. In various embodiments the vent 130 incorporates a breathable membrane, such as polytetrafluroethylene (PTFE) or other types of breathable membranes. The vent 130 can be a laminate or composite that includes a breathable membrane, such as a PTFE membrane laminated to a woven or non-woven support layer. In some embodiments, the vent 130 is a woven fabric or a non-woven fabric. The vent 130 can be constructed of hydrophobic material, or the vent 130 can be treated to exhibit hydrophobic properties. In one example, the vent 130 is a hydrophobic woven or non-woven fabric. The vent 130 can be constructed of an oleophobic material, or the vent 130 can be treated to exhibit oleophobic properties. In one example, the vent 130 is an oleophobic woven or non-woven fabric. In some embodiments the vent 130 has a support ring to support the periphery of the venting material.

In some other embodiments, the vent 130 is a nonbreathing vent, such as a relief valve that does not allow passive airflow therethrough during normal operation, but allows for pressure release upon a pressure spike within the mount opening 152 (such as a pressure spike originating within the enclosure 166) relative to the outside environment. In various embodiments where the vent 130 is a nonbreathing vent, the vent 130 can be bursting foil, tear-away foil, or elastomeric relief valve such as an umbrella valve or duckbill valve, for example. An “umbrella valve” is defined herein as a valve having a perimetric elastomeric lip that forms a seal with a perimetric surface about a venting opening, where the elastomeric lip is configured to unseal from the perimetric surface at a minimum pressure differential to allow for pressure equalization. In examples where the vent 130 is a foil, the vent 130 can be constructed of a metal foil or other type of material that is configured to release pressure upon a sufficient positive pressure differential between the mount opening 152 and the outside environment. Upon a sufficient positive pressure differential between the mount opening 152 and the outside environment, the vent 130 can be configured to fail. The vent 130 can burst, detach from the vent housing 120, or the vent 130 can expand until it contacts a puncturing mechanism 142 that causes the material to fail. In the current example, the vent 130 can be configured as a breathable vent having relief valve functionality, which will be described in more detail below.

The vent assembly 100 has a vent 130, a vent body 120 and a vent mount 150. The vent body 120 has a first axial end 102 and a second axial end 104. The vent body 120 is generally configured to house the vent 130. The vent body 120 can define a vent cavity 122a, 122b having an ambient side 122a and an enclosure side 122b. The ambient side 122a of the vent cavity is in direct fluid communication with the outside environment and the enclosure side 122b is configured to be in direct fluid communication with the enclosure 166. The enclosure side 122b and the ambient side 122a are in fluid communication through the vent 130. The enclosure side 122b can be positioned towards the second axial end 104. The ambient side 122a can be positioned towards the first axial end 102.

The vent 130 is coupled to a vent mount surface 132 of the vent body 120 around the airflow pathway 106. The vent 130 extends across the vent cavity 122a, 122b separating the ambient side 122a from the enclosure side 122b. The vent 130 is positioned in fluid communication with the housing opening 162 in the housing 160. The vent 130 can be coupled to the vent mount surface 132 of the vent body 120 with an adhesive, or with a weld such as a heat weld or ultrasonic weld. In some embodiments the vent body 120 is overmolded to the vent 130 to couple the vent 130 to the vent body 120. In some other embodiments, the vent 130 is overmolded to a vent frame that surrounds the vent 130, and the vent frame is coupled to the vent mount surface 132 of the vent body 120 with an adhesive or welding operation.

In the current example, a vent barrier 138 is configured to limit direct impact of environmental contaminants on the vent 130. For example, the vent barrier 138 can be configured to limit direct impact of water spray on the vent 130. Each vent barrier 138 is positioned across at least a portion of a corresponding environmental opening 124. The vent barriers 138 are disposed around the vent 130. Each of the vent barriers 138 extend axially from the vent 130 towards the first axial end 102 of the vent assembly 110. Each vent barrier 138 can be radially spaced from the vent 130. Each vent barrier 138 can be radially spaced from the environmental opening 124. In some embodiments the vent barrier can be omitted.

The coupling structure 108 of the vent assembly 110 is generally configured to couple the vent assembly 110 to the housing 160 about the housing opening 162 (visible in FIG. 3). The coupling structure 108 is mutually defined by the vent mount 150 and the vent body 120. The vent mount 150 is generally configured to be fixed to the housing 160. In various embodiments, the vent mount 150 is installed in the housing 160 during assembly of the housing 160. The vent mount 150 is configured to provide an interface through which the vent body 120 is removably coupled to the housing 160. The vent mount 150 defines a mount opening 152 that is configured for communication with the enclosure 166 and the vent cavity 122a, 122b. In the current example, the vent mount 150 defines a portion of the enclosure side 122b of the cavity.

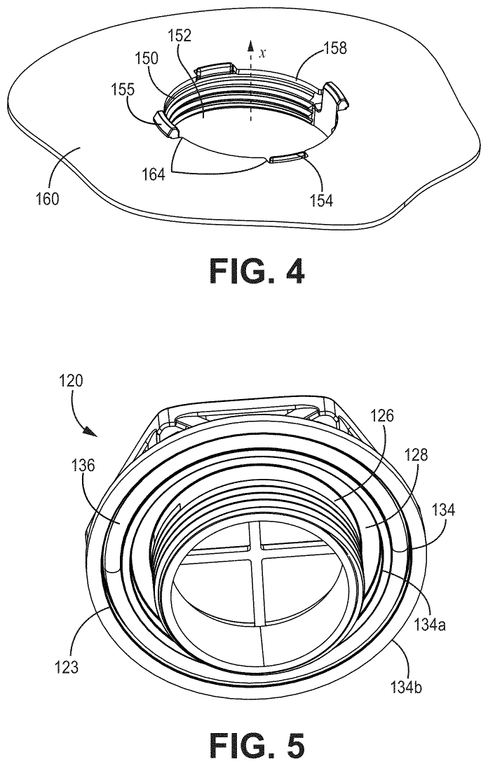

The vent mount 150 has a fastening feature 154, 155 configured to rotatably fix the vent mount 150 to the housing 160. FIG. 4 depicts the example vent mount 150 of previous examples mounting to the housing 160. The fastening feature 154, 155 is configured to rotatably fix the vent mount 150 to the housing 160 about the housing opening 162. “Rotatably fix” is used to mean that the vent mount 150 is obstructed from rotation relative to the housing 160. In various embodiments, the fastening feature 154, 155 is configured to establish and maintain axial alignment between the mount opening 152 and the housing opening 162. In some embodiments, the fastening feature 154, 155 is configured to allow limited axial translation of the vent mount 150 relative to the housing 160. As such, when the vent mount 150 is fixed to the housing 160 (prior to installation of the vent body 120), the vent mount 150 is axially translatable relative to the housing 160. In some other embodiments the fastening feature 154, 155 is configured to fix the vent mount 150 to the housing 160 in the axial direction.

In various examples, the fastening feature 154, 155 has a series of axial protrusions disposed around the mount opening 152. The axial protrusions extend in the axial direction. The axial protrusions are positioned radially outward from the mount opening 152. In various examples such as the one depicted, there are four axial protrusions. In some embodiments there are two or more axial protrusions. In some embodiments there are three or five axial protrusions. In some embodiments there are two axial protrusions. In some embodiments there are six or eight axial protrusions.

The axial protrusions can be equally spaced around the central axis. The axial protrusions are symmetric relative to the central axis x. In some embodiments, the axial protrusions are spaced 10° to 180° apart relative to the central axis x. In various embodiments, the axial protrusions are spaced 80° to 100° apart relative to the central axis x. In this particular example, the axial protrusions are angularly spaced 90° apart relative to the central axis x. The axial protrusions are configured to be received by the housing 160 around the housing opening 162. In this example, the axial protrusions are configured to be received by protrusion receptacles 164 defined by the housing 160. The protrusion receptacles 164 are positioned radially outward from the housing opening 162.

The vent mount 150 has a facing surface 156 that generally extends around the mount opening 152 and the axial protrusions 154, 155. The facing surface 156 will be discussed in more detail below. Each of the axial protrusions 154, 155 have an axial length/(visible in FIG. 2A) that is defined as the length of the axial protrusion extending axially beyond the facing surface 156. Each of the axial protrusions 154, 155 can have an axial length/ranging from about 1 mm to about 10 mm. Each of the axial protrusions have an axial length/ranging from about 1 mm to about 5 mm. Each of the axial protrusions have an axial length/ranging from about 1.5 mm to about 4 mm.

Each of the axial protrusions 154, 155 can have a width w (visible in FIG. 3) extending in a direction perpendicular to both the axial length l (visible in FIG. 2A) and the thickness t_{f} (visible in FIG. 2A) of the axial protrusion. The thickness t_{f} of each axial protrusion is the distance between the inner boundary and the outer boundary of the protrusion in the radial direction. In an example, the axial protrusions 154, 155 can have a thickness t_{f} of at least 0.5 mm. In an example, one or more axial protrusions 154, 155 can have a thickness t_{f} of about 2.6 mm or 1.0 mm. Each of the axial protrusions 154, 155 can have a width w ranging from 2 mm to 20 mm. Each of the axial protrusions 154, 155 can have a width w ranging from 5 mm to 10 mm. The axial protrusions can have a width w ranging from 6 mm to 8 mm. However, in some embodiments one or more of the axial protrusions 154, 155 can have a width w that is relatively longer, such as 30 mm to 70 mm or 40 mm to 60 mm. In some embodiments one or more of the axial protrusions 154, 155 can have a width w that is a percentage of the circumferential length of an annular pocket 128, such as 40% to 60%, 5% to 20%, as examples, where the annular pocket 128 is described in more detail below. In some embodiments, each of the axial protrusions defines a curvature along its width that is concentric to the curvature of the mount opening 152 relative to the central axis x.

The axial protrusions 154, 155, which include the fastening features 155 can be a variety of features and combinations of features. In the current example, the fastening feature 154, 155 includes a snap fit cantilever 155. The snap fit cantilever 155 is positioned radially outward from the mount opening 152. Particularly, the fastening feature 154, 155 includes a pair of snap fit cantilevers 155 on opposite sides of the mount opening 152 relative to the central axis x. The snap fit cantilevers 155 are configured to rotatably fix the vent mount 150 to the housing 160 about the housing opening 162. The snap fit cantilevers 155 are configured to retain the vent mount 150 on the housing 160. The snap fit cantilevers 155 are configured to maintain axial alignment between the vent mount 150 and the housing opening 162. In some embodiments, the snap fit cantilevers 155 prevent extraction of the vent mount 150 from the housing opening 162 or prevent the vent mount 150 from being decoupled from the housing 160 under the force of gravity. The snap fit cantilevers 155 can limit axial translation of the vent mount 150 relative to the housing opening 162 to a range.

Each of the snap fit cantilevers 155 has an engaging lip/edge 157 that is configured to engage the housing 160 about the housing opening 162. Each of the snap fit cantilevers 155 can be configured to apply a biasing force radially outward against the housing 160 about the housing opening 162 upon installation, which can maintain the position of the engaging lip 157 on the outer surface 161 of the housing 160. For installation, the snap fit cantilevers 155 are compressed radially inward to overcome the biasing force to be inserted in the housing opening 162, and then are released after insertion.

In this example the fastening feature 154, 155 also includes tabs 154 on opposite sides of the mount opening 152 relative to the central axis x. The tabs 154 are configured to rotatably fix the vent mount 150 to the housing 160 about the housing opening 162. In this example, the tabs 154 are positioned 90° from each snap fit cantilever 155 relative to the central axis x. The tabs 154 do not prevent extraction of the vent mount 150 from the housing opening 162. In some embodiments the tabs 154 may be omitted.

Each snap fit cantilever 155 can have an axial length that is greater than the axial length of each tab 154, in some embodiments. Each snap fit cantilever 155 can have an axial length that is equal to the axial length of each tab 154. Each snap fit cantilever 155 can have a width that is greater than the width of each tab 154, in some embodiments. Each snap fit cantilever 155 can have a width that is equal to the width of each tab 154. Each snap fit cantilever 155 can have a thickness that is greater than the thickness of each tab 154, in some embodiments. Each snap fit cantilever 155 can have a thickness that is equal to the thickness of each tab 154.

In some other embodiments, the fastening features can have alternate configurations and combinations of components. In some embodiments, only two fastening features are used. For example, the tabs 154 may be omitted and two snap fit cantilevers 155 can be used. In some embodiments, the fastening features can be three snap fit cantilevers. In some embodiments, the fastening feature can be one or more rivets that are configured to fix the vent mount to the housing. In some embodiments the fastening feature can be screws that are configured to fix the mounting structure to the housing. In some embodiments soldering or welding locations can be defined between the vent mount and the housing to fix the vent mount to the housing. Other fastening features are certainly contemplated.

The facing surface 156 of the vent mount 150 is defined around the mount opening 152. The facing surface 156 is generally configured to contact the housing 160 about the housing opening 162. The facing surface 156 is defined around the fastening features 154, 155. In various embodiments, at least a portion of the facing surface 156 is positioned radially outward from the fastening features 154, 155. The facing surface 156 is generally annular in shape, meaning it has an inner perimeter 156a and an outer perimeter 156b (particularly visible in FIGS. 2B and 3). In some embodiments the inner perimeter 156a and/or the outer perimeter 156b can define a circle, oval, polygon or another shape. The inner perimeter 156a of the facing surface 156 has an inner dimension mᵢ (noted in FIG. 2B), which can be an inner radius, from the central axis x. The inner dimension mᵢ of the facing surface 156 is generally greater than the radius r of the mount opening 152. The outer perimeter 156b of the facing surface 156 has an outer dimension mₒ, which can be an outer radius, from the central axis x.

In various embodiments, the facing surface 156 is configured to apply axial force to the housing 160 around the housing opening 162 when the vent assembly is installed in the housing 160. In various embodiments, the facing surface 156 is configured to apply axial force to the housing 160 in a direction outward from the enclosure 166. Particularly, the facing surface 156 is configured to apply outward force to an inner surface 163 of the housing 160 about the housing opening 162.

In various embodiments, the vent mount 150 is configured to be installed in the housing opening 162 of the housing 160 from the enclosure 166 side of the housing 160. As such, when installed, the vent mount 150 is configured to extend from the enclosure 166 through the housing opening 162 to the environment outside of the housing 160. The fastening feature 154, 155 of the vent mount 150 defines a housing insertion portion of the vent assembly 110 that is configured to extend through the housing opening 162 of the housing 160. The facing surface 156 is configured to abut the inner surface 163 of the housing 160 about the housing opening 162.

In various embodiments, the vent mount 150 is an anchor nut, meaning that the vent mount 150 is configured to have a rotatably fixed position relative to the vent body 120. The vent mount 150 has mating threads 158 disposed about the mount opening 152 that are configured to releasably engage the vent body 120. In various embodiments, when fixed to the housing 160, the vent mount 150 is configured to position the mating threads 158 within the enclosure 166 to be engageable by the vent body 120 from outside of the enclosure 166.

The vent body 120 is generally configured to be installed in the housing 160 to allow pressure equalization between the enclosure 166 and the environment outside of the housing 160. The vent body 120 is generally configured to releasably engage the vent mount 150. In various embodiments, the vent body 120 is configured to form a seal about the housing opening 162 when coupled to the vent mount 150. In various embodiments, the vent body 120 and the vent mount 150 are configured to apply axial compression to the housing 160 about the housing opening 162. Such a configuration may advantageously create a reliable and robust seal around the housing opening 162.

The vent body 120 generally defines a vent cavity 122a, 122b, a first axial end 102, and a second axial end 104 (see FIG. 3). The vent cavity 122a, 122b extends between the first axial end 102 and the second axial end 104. The vent body 120 defines circumferential threads 126 positioned towards the second axial end 104. The circumferential threads 126 are configured to releasably engage the mating threads 158 of the vent mount 150.

In the current example, the circumferential threads 126 define a housing insertion portion of the vent assembly 110 that is configured to be inserted through the housing opening 162 in the housing 160. The circumferential threads 126 extend around a cylindrical component 127 of the insertion portion of the vent assembly 110. The cylindrical component 127 has an axial length along the central axis x. When the vent assembly 110 is installed in the housing 160, the cylindrical component 127 extends through the housing opening 162. The axial protrusions 154, 155 discussed above with reference to the vent mount 150 also are components of the insertion portion of the vent assembly 110. The axial protrusions 154, 155 are configured to be disposed around the cylindrical component 127. The axial protrusions 154, 155 are configured to be positioned radially outward from the cylindrical component 127.

The vent assembly 100 has a sealing surface 134 that is configured to form a seal with the housing 160 about the housing opening 162. The sealing surface 134 can be a seal 136 disposed in a seal receptacle 123, for example, which are particularly visible in FIGS. 2A and 5. The seal 136 is generally constructed of an elastomeric material. The sealing surface 134 generally surrounds the housing insertion portion of the vent assembly 110, which, in the current example, means that the sealing surface 134 surrounds the cylindrical component 127 and the axial protrusions 154, 155. The sealing surface 134 is configured to surround the housing opening 162 about the central axis x. The sealing surface 134 generally surrounds the vent cavity 122a, 122b. The sealing surface 134 is generally annular in shape, meaning it has an inner perimeter 134a and an outer perimeter 134b. In some embodiments the inner perimeter 134a and/or the outer perimeter 134b can define a circle, oval, polygon or another shape. The inner perimeter 134a of the sealing surface 134 has an inner dimension dᵢ (visible in FIG. 2B), which can be an inner radius, from the central axis x. The inner dimension dᵢ of the sealing surface 134 can be greater than the corresponding dimension (such as a radius from the central axis x) of the enclosure side 122b of the vent cavity. The outer perimeter 134b of the sealing surface 134 has an outer dimension dₒ, which can be an outer radius, from the central axis x. In the current example, the sealing surface 134 faces the second axial end 104 of the vent body 120, where “faces” is used herein to mean that the surface is oriented towards the specified direction. In various embodiments, the sealing surface 134 is configured to form a seal with an outer surface 161 of the housing 160.

To install the vent assembly 110 in the housing 160, the cylindrical component 127 is inserted through the housing opening 162 and into the mount opening 152. The vent body 120 is rotated relative to the housing 160 and the vent mount 150 such that the circumferential threads 126 and the mating threads 158 mutually engage. As the vent body 120 is threaded to the vent mount 150, the vent body 120 and/or the vent mount 150 advance towards each other in the axial direction until they exert compression on the housing 160 about the housing opening 162. In particular, the sealing surface 134 and the facing surface 156 axially translate together until they collectively exert compression on the housing 160 about the housing opening 162. The sealing surface 134 and the facing surface 156 are configured to collectively exert compression on the housing 160 such that the sealing surface 134 forms a seal with the housing 160.

In some embodiments, the vent body 120 can be configured as an expanding push-in screw rivet that is configured to be at least partially installed in the vent mount 150 by being pushed into the mount opening 152. In some such embodiments, after pushing the vent body 120 into the mount opening 152, the vent body 120 is rotated to further advance the circumferential threads 126 of the vent body 120 into the enclosure along the mating threads 158 of the vent mount 150 to establish compression on the housing 160, which forms a seal about the housing opening 162. In some other embodiments, the vent body 120 is pushed into the vent mount 150 until sufficient compression is achieved on the housing 160 to form a seal about the housing opening 162.

In some embodiments, the vent body 120 is configured to be removable from the vent mount 150. In embodiments the vent body 120 is removed from the vent mount 150 by rotating the vent body 120 relative to the vent mount 150 to disengage the circumferential threads 126 from the mating threads 158. The vent body 120 may be removed for a variety of reasons including for replacement of the vent body 120 or for accessing the enclosure 166 through the housing opening 162. In some embodiments, the vent body 120 can be repeatedly installed and removed from the vent mount 150. In other embodiments, the vent assembly 110 can define a self-destructing feature that is activated upon removal of the vent body 120 from the vent mount 150. The self-destructing feature could be an interference tab integrated into the vent body 120, for example, that is dislodged upon removal of the vent body 120 from the vent mount 150, and interferes with re-installation of the vent body 120 in the vent mount 150. Such a feature may advantageously prevent use of a vent body 120 that is no longer operational.

The sealing surface 134 and the facing surface 156 are generally configured to compress a portion of the housing 160 in the axial direction about the housing opening 162. The sealing surface 134 and the facing surface 156 are generally configured to axially oppose each other upon installation in the housing 160, meaning that the sealing surface 134 and the facing surface 156 are configured to overlap in the axial direction when installed on the housing 160. The outer dimension dₒ, which may be a radius, of the sealing surface 134 is generally greater than the inner dimension mᵢ, which may be an inner radius, of the facing surface 156. Similarly, the outer dimension mₒ of the facing surface 156 is generally greater than the inner dimension dᵢ of the sealing surface 134. Overlap in the axial direction between the sealing surface 134 and the facing surface 156 may advantageously limit deformation of the housing 160 upon compression of the housing 160 between the sealing surface 134 and the facing surface 156. Such an advantage can be particularly notable where the housing 160 is relatively thin and deformable.

In the current example, the vent body 120 is configured to accommodate portions of the vent mount 150 that extend to the outside of the housing 160. In particular, the vent body 120 defines an annular pocket 128 that is configured to receive a portion of the fastening features 154, 155. The annular pocket 128, which is particularly visible in FIGS. 2A, 2B, and 5, is configured to accommodate translation of the distal end of each of the fastening features 154, 155 about the central axis x as the vent body 120 is rotated relative to the vent mount 150 for installation of the vent body 120. The annular pocket 128 can be around the vent cavity 122a, 122b. The annular pocket 128 can be around the enclosure side 122b of the vent cavity. The annular pocket 128 can be positioned radially between the circumferential threads 126 and the sealing surface 134. In various embodiments, the inner dimension dᵢ of the sealing surface 134 is greater than or equal to the outer radius Ro of the annular pocket 128.

The annular pocket 128 can be recessed from the sealing surface 134. The annular pocket 128 can extend axially from the sealing surface 134 towards the first axial end 102 of the vent body 120. The annular pocket 128 extends in the axial direction to define a pocket depth d (see FIG. 2A). The pocket depth d can define a maximum length of the fastening feature 154, 155 extending axially beyond the outer surface of the housing 160 that can be accommodated by the annular pocket 128. In some embodiments the annular pocket 128 has a pocket depth d ranging from 1 mm to 20 mm. In some embodiments the annular pocket 128 has a depth d ranging from 2 mm to 10 mm or 2 mm to 5 mm. The annular pocket 128 can also have a pocket thickness tₚ (visible in FIG. 2B) extending between an inner radius Ri and an outer radius Ro of the annular pocket. The pocket thickness tₚ can define a maximum thickness t_{f} of the fastening feature 154, 155 that can be accommodated by the annular pocket 128. The annular pocket has a pocket thickness tₚ ranging from 3 mm to 15 mm, 4 mm to 10 mm, or 5 mm to 8 mm. In various embodiments, the curvature of the annular pocket 128 is equal to the curvature of each of the fastening features 154, 155.

The distance between the sealing surface 134 and the facing surface 156 when the annular pocket 128 receives the maximum axial length of the fastening feature(s) 154, 155 can define the minimum wall thickness that the vent assembly 110 is configured to be coupled to. For example, in an alternate example vented housing 200 depicted in FIG. 2B, the vent assembly 110 is installed on a housing 170 having a thinner wall than the housing 160 depicted in FIG. 2A. The housing 170 has the minimum wall thickness that the vent assembly 110 is configured to accommodate, where at least one of the fastening features 155 is fully received by the depth of the annular pocket 128 and, thus, the sealing surface 134 and the facing surface 156 are the minimum distance apart where a seal can still be formed with the housing 170.

In embodiments consistent with the currently-described example, the maximum wall thickness that the vent assembly 110 is configured to accommodate is defined by the axial distance between the facing surface 156 and the engaging edge 157 of the snap-fit cantilever 155. If the wall thickness is greater than the axial distance between the axial distance between the facing surface 156 and the engaging edge 157 of the snap-fit cantilever 155, then snap fit cantilever 155 would not be able to engage the outside surface of the housing 160 from the inside surface of the housing 160. FIG. 2A can be consistent with an example maximum wall thickness that could be accommodated by the vent assembly 110.

In some embodiments, the first axial end 102 of the vent body 120 is configured to be positioned outside of the housing 160, and the second axial end 104 is configured to be positioned in the enclosure 166. In some embodiments, both the first axial end 102 and the second axial end 104 of the vent body 120 are configured to be positioned outside the housing 160, however.

The vent body 120 has a vent cover 140 in a variety of embodiments. The vent cover 140 is generally configured to extend across the vent 130. The vent cover 140 can be configured to protect the vent 130 from impact from materials in the outside environment such as water and debris. In some embodiments, the vent cover 140 lacks openings that extend in the axial direction. In some other embodiments, the vent cover 140 can define one or more openings extending in the axial direction. In some embodiments the vent cover 140 is a single cohesive component with the vent body 120. In some other embodiments, the vent cover 140 is coupled to the vent body 120 such as through a snap fit connection or through the use of fasteners or adhesives.

Vent assemblies consistent with the present technology can have a variety of functions and combinations of functions. In the examples consistent with FIGS. 1-5, the vent body 120 has relief valve functionality. In particular, as visible in FIGS. 2A and 2B, the vent cover 140 has one or more puncturing mechanisms 142 extending from the vent cover 140 towards the vent 130. Upon a pressure spike within the enclosure side 122b of the cavity (such as via a pressure spike originating in the enclosure 166) beyond a threshold, the vent 130 may expand towards the puncturing mechanism 142. If the vent 130 and the puncturing mechanism 142 make sufficient contact, then the vent 130 is punctured, which allows the rapid release of air to the ambient side 122a of the cavity, to the outside environment. Upon such an occurrence, the vent body 120 would generally be replaced. In variety embodiments, absent such a pressure spike within mount opening 152 (and, in particular, in the enclosure 166) relative to the outside environment, the vent 130 is a breathable vent that allows passive airflow between the ambient side 122a and the enclosure side 122b of the cavity. Particularly, the vent 130 allows passive airflow between the enclosure 166 and the outside environment.

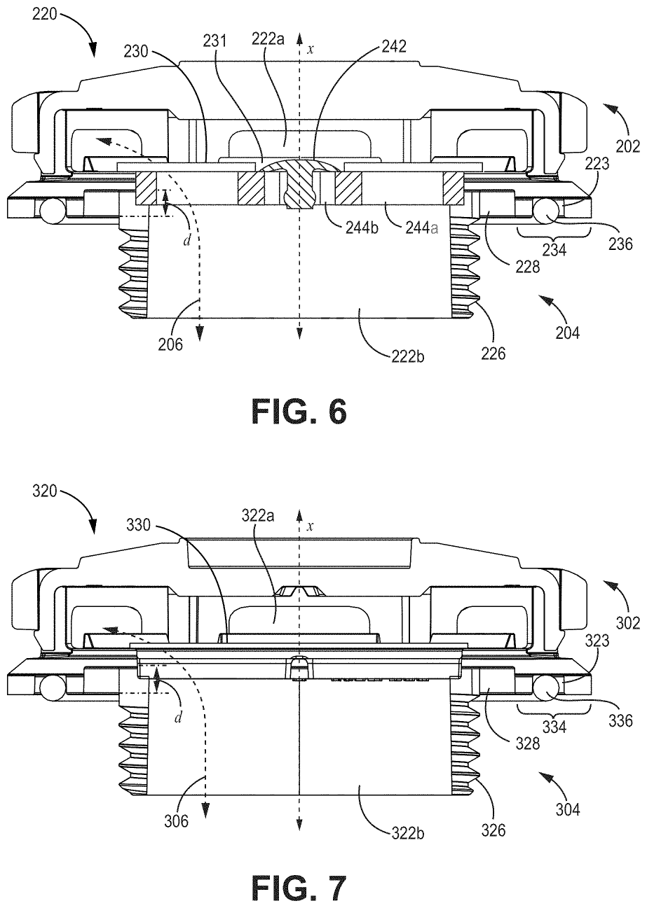

FIG. 6 depicts another example vent body 220 that can be used with vent mounts described herein. The vent body 220 is configured to allow for passive venting between an enclosure and an outside environment. In the current embodiment, the vent body 220 also has relief valve functionality. The discussions of vent bodies elsewhere herein generally apply to the currently described vent body 220, unless inconsistent with the present description or figure.

The vent body 220 is configured to be removably installed in a vent mount that is fixed to a housing, where the vent mount can be consistent with descriptions above. The vent body 220 defines a vent cavity 222a, 222b having an enclosure side 222b and an ambient side 222a. The vent body 220 has a vent 230 disposed in the vent cavity 222a, 222b that extends across the vent cavity 222. The enclosure side 222b and the ambient side 222a are in fluid communication through the vent 230. The vent body 220 defines a first axial end 202 and a second axial end 204. An airflow pathway 206 extends through the vent cavity 222a, 222b and the vent 230.

The vent body 220 defines circumferential threads 226 positioned towards the second axial end 204. The circumferential threads 226 are configured to releasably engage the mating threads of a vent mount, similar to vent mounts described herein. The vent body 220 has a sealing surface 234 that is configured to form a seal with the housing about a housing opening. The sealing surface 234 faces the second axial end 204 of the vent body 220. The sealing surface 234 can include a seal 236 disposed in a seal receptacle 223, for example.

The vent body 220 defines an annular pocket 228 about the vent cavity 222a, 222b having a depth din the axial direction. The annular pocket 228 particularly extends around the enclosure side 222b of the cavity. The annular pocket 228 is open towards the second axial end 204 and extends axially towards the first axial end 202. The annular pocket 228 can be configured to receive and allow translation of a distal end of a fastening feature of a corresponding vent mount therein when, for example, the vent body 220 is threaded to the vent mount, for example. The annular pocket 228 can be consistent with those described elsewhere herein.

The vent body 220 and vent 230 can be consistent with descriptions already provided herein except that, in the current implementation, the vent 230 has an annular shape, rather than a disk shape as disclosed above, and defines a vent opening 231. The vent 230 extends across a first vent body opening 244a between the enclosure side 222b of the cavity and the ambient side 222a of the cavity. In the current example, the vent 230 is a passive airflow vent.

A relief valve 242 is disposed in the vent opening 231 defined by the vent 230, where the relief valve 242 is considered another, second vent. In the current example, the passive airflow vent 230 and the relief valve 242 are arranged in parallel relative to airflow through the vent body 220. The relief valve 242 extends across a second vent body opening 244b defined by the vent body 220. The relief valve 242 is disposed between the enclosure side 222b of the cavity and the ambient side 222a of the cavity. The relief valve 242 is configured to be biased in a closed position during normal operating conditions. Upon a pressure spike within the enclosure side 222b of the cavity beyond a threshold, the relief valve 242 is configured to open to allow the release of air into the ambient side 222a of the cavity, which extends to the environment outside of the enclosure. In various embodiments, upon the pressure within the enclosure side 222b of the cavity returning to a level below the threshold, the relief valve 242 closes again to resume normal operating conditions with passive airflow through the vent 230. In the current example, the relief valve 242 is an umbrella-shaped valve, but other types of biased valves can also be used such as a duckbill valve, for example.

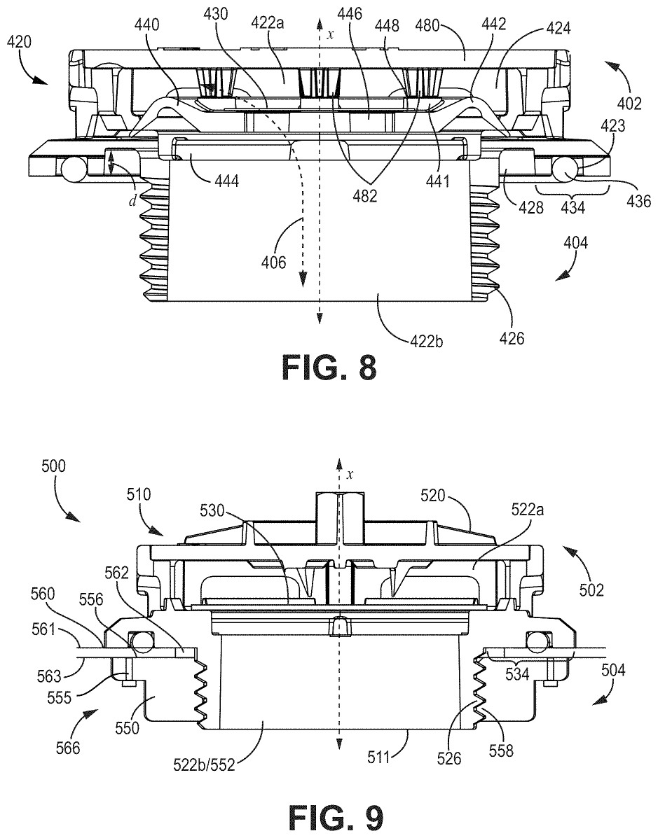

In an alternative configuration, the positions of the passive airflow vent 230 and the relief valve 242 can be reversed, such that the relief valve 242 is positioned, in part, radially outward from the vent 230. In such an example, the vent 230 can be coupled to the vent body 220 across a vent opening, where the vent 230 is positioned within an opening defined by the relief valve 242. The vent 230 can alternatively be positioned on the relief valve 242 itself across vent openings defined by the relief valve 242. Such an example is discussed with reference to FIG. 8, below.

FIG. 7 depicts yet another example vent body 320 that can be used with vent mounts described herein. The vent body 320 is configured to allow for passive venting between an enclosure and an outside environment. In the current embodiment, the vent body 320 may or may not have relief valve functionality, which will be discussed in more detail, below. The discussions of vent bodies elsewhere herein generally apply to the currently described vent body 320, unless inconsistent with the present description or figure.

The vent body 320 is configured to be removably installed in a vent mount that is fixed to a housing. The vent body 320 defines a vent cavity 322a, 322b having an enclosure side 322b and an ambient side 322a. The vent body 320 has a vent 330 disposed in the vent cavity 322a, 322b that extends across the vent cavity. The ambient side 322a and the enclosure side 322b are in fluid communication through the vent 330. The vent body 320 defines a first axial end 302 and a second axial end 304. An airflow pathway 306 extends through the vent cavity 322a, 322b and the vent 330.

The vent body 320 defines circumferential threads 326 positioned towards the second axial end 304. The circumferential threads 326 are configured to releasably engage the mating threads of a vent mount, similar to vent mounts described herein. The vent body 320 has a sealing surface 334 that is configured to form a seal with the housing about a housing opening. The sealing surface 334 faces the second axial end 304 of the vent body 320. The sealing surface 334 can include a seal 336 disposed in a seal receptacle 323, for example.

The vent body 320 defines an annular pocket 328 about the vent cavity 322a, 322b having a depth din the axial direction. The annular pocket 328 is open towards the second axial end 304 and extends towards the first axial end 302. The pocket opening generally faces the second axial end 304. The annular pocket 328 can be configured to receive and allow translation of a distal end of a fastening feature of a corresponding vent mount therein when, for example, the vent body 320 is threaded to a vent mount, for example. The annular pocket 328 can be consistent with those described elsewhere herein.

The vent body 320 and vent 330 can be consistent with descriptions already provided herein. Similar to embodiments described above with reference to FIGS. 1-5, in the current example, the vent 330 is in the shape of a disk. In some examples consistent with the current figure, the vent body 320 does not have relief valve functionality. In some other examples consistent with the current figure, upon a pressure spike within the enclosure side 522b of the cavity that is beyond a threshold pressure, the vent 330 is configured to burst or tear away from the vent body 320 to allow the rapid release of air into the ambient side 322a of the cavity, which leads to the environment outside of the enclosure. The vent 330 can be configured to tear away from the vent body 320 such as through a failure of an adhesive that couples the vent 330 to the vent body 320. Alternatively, the vent 330 can be configured to burst through a material failure of the vent 330 upon a pressure spike beyond the threshold pressure.

FIG. 8 depicts another example vent body 420 that can be used with vent mounts described herein. The vent body 420 is configured to allow for passive venting between an enclosure and an outside environment. In the current embodiment, the vent body 420 also has relief valve functionality. The discussions of vent bodies elsewhere herein generally apply to the currently described vent body 420, unless inconsistent with the present description or figure.

The vent body 420 is configured to be removably installed in a vent mount that is fixed to a housing, where the vent mount can be consistent with descriptions above. The vent body 420 defines a vent cavity 422a, 422b having an enclosure side 422b and an ambient side 422a. The vent body 420 has a vent 430 disposed in the vent cavity 422a, 422b. The vent 430 extends across the vent cavity 422. The enclosure side 422b and the ambient side 422a are in fluid communication through the vent 430. The vent body 420 defines a first axial end 402 and a second axial end 404. An airflow pathway 406 extends through the vent cavity 422a, 422b and the vent 430.

The vent body 420 defines circumferential threads 426 positioned towards the second axial end 404. The circumferential threads 426 are configured to releasably engage the mating threads of a vent mount, similar to vent mounts described herein. The vent body 420 has a sealing surface 434 that is configured to form a seal with the housing about a housing opening. The sealing surface 434 faces the second axial end 404 of the vent body 420. The sealing surface 434 can include a seal 436 disposed in a seal receptacle 423, for example.

The vent body 420 defines an annular pocket 428 about the vent cavity 422a, 422b having a depth din the axial direction. The annular pocket 428 particularly extends around the enclosure side 422b of the cavity. The annular pocket 428 is open towards the second axial end 404 and extends axially towards the first axial end 402. The annular pocket 428 can be configured to receive and allow translation of a distal end of a fastening feature of a corresponding vent mount therein when, for example, the vent body 420 is threaded to the vent mount. The annular pocket 428 can be consistent with those described elsewhere herein.

The vent body 420 and first vent 430 can be consistent with descriptions already provided herein. In the current implementation, the first vent 430 has a disk shape. The first vent 430 is disposed across an opening 446. The first vent 430 is disposed between the enclosure side 422b of the cavity and the ambient side 422a of the cavity.

A relief valve 440 is disposed across an opening 444 defined by the vent body 420, where the relief valve 440 is considered second vent within the vent body 420, but is referred to as the “relief valve” for clarity herein. The relief valve 440 is configured to be biased in a closed position during normal operating conditions. Upon a pressure spike within the enclosure side 422b of the cavity beyond a threshold, the relief valve 440 is configured to open to allow the release of air into the ambient side 422a of the cavity, which extends to the environment outside of the enclosure. In various embodiments, upon the pressure within the enclosure side 422b of the cavity returning to a level below the threshold, the relief valve 440 closes again to resume normal operating conditions with passive airflow through the vent 430. In the current example, the relief valve 440 is an elastomeric valve. More particularly, the relief valve 440 is an umbrella valve, but other types of biased valves can also be used such as a duckbill valve, for example.

In the current example, the relief valve 440 and the vent 430 collectively extend across the valve body opening 444. The relief valve 440 is mounted directly to the vent body 420. The relief valve 440 defines a vent opening(s) 446 and a vent mounting surface 448 about each vent opening 446. The vent 430 is coupled to each vent mounting surface 448 across each vent opening 446. In various embodiments, the relief valve 440 is configured to protect the vent 430 against impact by foreign materials, such as water or debris. In the current example, the vent mounting surface 448 of the relief valve 440 is surrounded by an outer portion 442 of the relief valve 440. Here, the outer portion 442 of the relief valve 440 is an elastomeric lip 442 of the umbrella valve 440. In the current example, the vent mounting surface 448, and therefore the vent 430, is recessed in the axial direction relative to the outer portion 442 of the relief valve 440. As such, the outer portion 442 of the relief valve 440 is positioned radially between the vent 430 and perimetric environmental openings 424 defined by the vent body 420. Also, the outer portion 442 of the relief valve 440 extends axially at least from the vent mounting surface 448 towards the first end 402 of the vent body 420, beyond the thickness of the vent 430.

In some other examples, a vent mounting surface can be defined by the vent body rather than by the relief valve, and the relief valve can define a central opening that surrounds and exposes the vent mounting surface such that the vent can be coupled directly to the vent body within the opening of the relief valve.

Returning to the current figure, the relief valve 440 has a plurality of engagement features 441 that are configured to be engaged by corresponding mating features 482 of the vent cover 480. In some embodiments, each mating feature 482 frictionally engages a corresponding engagement feature 441. In some embodiments, when the vent cover 480 is coupled to the rest of the vent body 420, the mating features 482 and the vent body 420 compressibly engage the relief valve 440. In the current example, the engagement features 441 are sockets defined by the relief valve 440 and the mating features 482 are protrusions that are inserted into and frictionally engage the sockets. Other configurations are possible, however.

FIG. 9 depicts yet another example vented housing 500 incorporating a vent assembly 510 and a housing 560 consistent with the technology disclosed herein. The vent assembly 510 has a vent body 520 and a vent 530 disposed in the vent body 520. The discussions elsewhere herein generally apply to the currently described vent body 520, unless inconsistent with the present description or figure. The vent body 520 defines a vent cavity 522a, 522b and the vent 530 extends across the vent cavity 522a, 522b. The vent body 520 has a first axial end 502 and a second axial end 504. The vent body 520 defines circumferential threads 526 positioned towards the second axial end 504. The vent body 520 has a sealing surface 534 surrounding the vent cavity 522a, 522b. In the current example, the sealing surface 534 is surrounding the enclosure side 522b of the vent cavity. The sealing surface 534 faces the second axial end 504 of the vent body 520.

The vent assembly 510 has a vent mount 550 defining a mount opening 552. The discussions elsewhere herein generally apply to the currently described vent mount 550, unless inconsistent with the present description or figure. When installed in the housing 560, the mount opening 552 overlaps with the enclosure side 522b of the vent cavity towards the second axial end 504 of the vent body 520. The vent mount 550 has mating threads 558 configured to releasably engage the circumferential threads of the vent body 520. The vent mount 550 has a facing surface 556 about the mount opening 552 that is configured to oppose the sealing surface 534 of the vent body 520 when the vent assembly 510 is installed in the housing 560. The vent mount 550 has a fastening feature 555 configured to rotatably fix the vent mount 550 to the housing 560.

In the current example the vent mount 550 is an anchor nut. The vent mount 550 is configured to be rotatably and axially fixed to the housing 560. The vent mount 550 is configured to be rotatably and axially fixed to an inner surface 563 of the housing 560. Unlike examples discussed above, in the current example the vent mount 550 does not have a snap fit cantilever or tabs that serve as a fastening feature. In the current example, the fastening feature 555 of the vent mount 550 is a plurality of rivets or screws that are configured to fix the vent mount 550 to the housing 560.

Similar to previous embodiments, the vent body 520 and the vent mount 550 are configured to exert axial compression on the housing 560 about the housing opening 562. Unlike some previous embodiments, in the current example the vent body 520 does not define an annular pocket surrounding the vent cavity 522a, 522b.

Embodiment 1. An enclosure vent assembly comprising: a vent body defining a vent cavity, a first axial end, a second axial end, circumferential threads positioned towards the second axial end, and a sealing surface surrounding the vent cavity and facing the second axial end;

a vent disposed in the vent body, wherein the vent extends across the vent cavity; and
a vent mount defining a mount opening, mating threads configured to releasably engage the circumferential threads, a facing surface about the mount opening configured to oppose the sealing surface, and a fastening feature configured to rotatably fix the vent mount to a housing.

Embodiment 2. The enclosure vent assembly of any one of embodiments 1 and 3-10, wherein the vent mount is an anchor nut.

Embodiment 3. The enclosure vent assembly of any one of embodiments 1-2 and 4-10, wherein the fastening feature comprises a snap fit cantilever.

Embodiment 4. The enclosure vent assembly of any one of embodiments 1-3 and 5-10, wherein the snap fit cantilever is positioned radially outward from the mount opening.

Embodiment 5. The enclosure vent assembly of any one of embodiments 1-4 and 6-10, wherein the vent body defines an annular pocket about the vent cavity that extends in the axial direction and is configured to receive the snap fit cantilever.

Embodiment 6. The enclosure vent assembly of any one of embodiments 1-5 and 7-10, wherein the fastening feature comprises one of rivets and screws.

Embodiment 7. The enclosure vent assembly of any one of embodiments 1-6 and 8-10, wherein the sealing surface and the facing surface are configured to apply axial compression to the housing.

Embodiment 8. The enclosure vent assembly of any one of embodiments 1-7 and 9-10, wherein the vent mount is configured to be axially translatable relative to the housing.

Embodiment 9. The enclosure vent assembly of any one of embodiments 1-8 and 10, wherein the vent is a passive airflow vent.

Embodiment 10. The enclosure vent assembly of any one of embodiments 1-9, wherein the vent is a relief valve.

Embodiment 11. A vented housing comprising:

a housing defining an enclosure and a housing opening in communication with the enclosure;
a vent mount comprising a fastening feature that is rotatably fixed to the housing about the housing opening within the enclosure; and
an enclosure vent comprising a vent body defining a vent cavity and a vent, wherein the vent is disposed in the vent body across the vent cavity, and wherein the vent mount releasably engages the vent body.

Embodiment 12. The vented housing of any one of embodiments 11 and 13-20, wherein the vent mount and the enclosure vent are configured to apply axial compression to the housing about the housing opening.

Embodiment 13. The vented housing of any one of embodiments 11-12 and 14-20, wherein the vent mount is an anchor nut.

Embodiment 14. The vented housing of any one of embodiments 11-13 and 15-20, wherein the fastening feature comprises a snap fit cantilever.

Embodiment 15. The vented housing of any one of embodiments 11-14 and 16-20, wherein the vent mount defines a mount opening and the snap fit cantilever is positioned radially outward from the mount opening.

Embodiment 16. The vented housing of any one of embodiments 11-15 and 17-20, wherein the vent body defines an annular pocket around the vent cavity that extends in an axial direction and is configured to receive the snap fit cantilever.

Embodiment 17. The vented housing of any one of embodiments 11-16 and 18-20, wherein the fastening feature comprises one of rivets and screws.

Embodiment 18. The vented housing of any one of embodiments 11-17 and 19-20, wherein the enclosure vent defines a sealing surface around the vent cavity and the vent mount defines a facing surface around the vent cavity, and wherein the facing surface and the sealing surface are configured to apply axial compression to the housing.

Embodiment 19. The vented housing of any one of embodiments 11-18 and 20, wherein the vent is a passive airflow vent.

Embodiment 20. The vented housing of any one of embodiments 11-19, wherein the vent is a relief valve.

Embodiment 21. A vent assembly comprising:

a vent body defining a vent cavity, a first axial end, a second axial end,
circumferential threads positioned towards the second axial end, a sealing surface surrounding the vent cavity and facing the second axial end, and an annular pocket about the vent cavity having a depth in the axial direction; and
a vent disposed in the vent body, wherein the vent extends across the vent cavity.

Embodiment 22. The vent assembly of any one of embodiments 21 and 23-33, wherein the vent comprises a PTFE membrane.

Embodiment 23. The vent assembly of any one of embodiments 21-22 and 24-33, wherein the vent is a passive airflow vent.

Embodiment 24. The vent assembly of claim 23, further comprising a relief valve in parallel with the passive airflow vent with respect to airflow through the vent body.

Embodiment 25. The vent assembly of claim 24, wherein the relief valve is an umbrella valve defining a vent opening and a vent mounting surface about the vent opening, and the passive airflow vent is coupled to the vent mounting surface across the vent opening.

Embodiment 26. The vent assembly of claim 25, wherein the passive airflow vent is recessed in the axial direction from an outer portion of the relief valve.

Embodiment 27. The vent assembly of any one of embodiments 21-23 and 28-33, wherein the vent is a relief valve.

Embodiment 28. The vent assembly of any one of embodiments 21-27 and 29-33, wherein the annular pocket is positioned radially between the circumferential threads and the sealing surface.

Embodiment 29. The vent assembly of any one of embodiments 21-28 and 30-33, wherein the annular pocket extends axially from the sealing surface towards the first axial end.

Embodiment 30. The vent assembly of any one of embodiments 21-29 and 31-33, wherein the annular pocket has an axial depth ranging from 2 mm to 20 mm.

Embodiment 31. The vent assembly of any one of embodiments 21-30 and 32-33, wherein the annular pocket has a width ranging from 4mm to 15mm.

Embodiment 32. The vent assembly of any one of embodiments 21-31 and 33, further comprising a vent cover extending across the first axial end of the vent body.

Embodiment 33. The vent assembly of any one of embodiments 21-32, the vent cover comprising a puncturing mechanism extending from the cover towards the vent.

Embodiment 34. A vent assembly comprising:

a housing insertion portion configured to be inserted through an opening in a housing, the housing insertion portion comprising:
a cylindrical component having an axial length along a central axis, and four axial protrusions configured to be disposed around the cylindrical component,
wherein each of the four axial protrusions extend in the axial direction and are configured to be positioned radially outward from the cylindrical component, and wherein the four axial protrusions are spaced 80° to 100° apart relative to the central axis; and
a sealing surface surrounding the cylindrical component and the sealing surface configured to surround the four axial protrusions.

Embodiment 35. The vent assembly of any one of embodiments 34 and 36-45, wherein the four axial protrusions are spaced 90° apart.

Embodiment 36. The vent assembly of any one of embodiments 34-35 and 37-45, wherein each axial protrusion has an axial length ranging from 1 mm to 10 mm.

Embodiment 37. The vent assembly of any one of embodiments 34-36 and 38-45, wherein each axial protrusion has a width ranging from 3 mm to 15 mm.

Embodiment 38. The vent assembly of any one of embodiments 34-37 and 39-45, further comprising a vent coupled to the housing insertion portion.

Embodiment 39. The vent assembly of any one of embodiments 34-38 and 40-45, wherein the vent is a passive airflow vent.

Embodiment 40. The vent assembly of embodiment 39, further comprising a relief valve in parallel with the passive airflow vent with respect to airflow through the vent body.

Embodiment 41. The vent assembly of embodiment 40, wherein the relief valve is an umbrella valve defining a vent opening and a vent mounting surface about the vent opening, and the passive airflow vent is coupled to the vent mounting surface across the vent opening.

Embodiment 42. The vent assembly of embodiment 41, wherein the passive airflow vent is recessed in the axial direction from an outer portion of the relief valve.

Embodiment 43. The vent assembly of any one of embodiments 34-39 and 44-45, wherein the vent is a relief valve.

Embodiment 44. The vent assembly of any one of embodiments 34-43 and 45, further comprising a facing surface that is configured to oppose the sealing surface, wherein the facing surface is positioned radially outward from the axial protrusions.

Embodiment 45. The vent assembly of any one of embodiments 34-44, wherein two of the axial protrusions comprise snap fit cantilevers.

It should also be noted that, as used in this specification and the appended claims, the phrase “configured” describes a system, apparatus, or other structure that is constructed to perform a particular task or adopt a particular configuration. The word “configured” can be used interchangeably with similar words such as “arranged”, “constructed”, “manufactured”, and the like.

All publications and patent applications in this specification are indicative of the level of ordinary skill in the art to which this technology pertains. All publications and patent applications are herein incorporated by reference to the same extent as if each individual publication or patent application was specifically and individually indicated by reference. In the event that any inconsistency exists between the disclosure of the present application and the disclosure(s) of any document incorporated herein by reference, the disclosure of the present application shall govern.

This application is intended to cover adaptations or variations of the present subject matter. It is to be understood that the above description is intended to be illustrative, and not restrictive, and the claims are not limited to the illustrative embodiments as set forth herein.

1. An enclosure vent assembly comprising:
a vent body defining a vent cavity, a first axial end, a second axial end, circumferential threads positioned towards the second axial end, and a sealing surface surrounding the vent cavity and facing the second axial end;
a vent disposed in the vent body, wherein the vent extends across the vent cavity; and
a vent mount defining a mount opening, mating threads configured to releasably engage the circumferential threads, a facing surface about the mount opening configured to oppose the sealing surface, and a fastening feature configured to rotatably fix the vent mount to a housing.

2. The enclosure vent assembly of claim 1, wherein the vent mount is an anchor nut.

3. The enclosure vent assembly of claim 1, wherein the fastening feature comprises a snap fit cantilever.

4. The enclosure vent assembly of claim 3, wherein the snap fit cantilever is positioned radially outward from the mount opening.

5. The enclosure vent assembly of claim 3, wherein the vent body defines an annular pocket about the vent cavity that extends in the axial direction and is configured to receive the snap fit cantilever.

6. The enclosure vent assembly of claim 1, wherein the fastening feature comprises one of rivets and screws.

7. The enclosure vent assembly of claim 1, wherein the sealing surface and the facing surface are configured to apply axial compression to the housing.

8. The enclosure vent assembly of claim 1, wherein the vent mount is configured to be axially translatable relative to the housing.

9. The enclosure vent assembly of claim 1, wherein the vent is a passive airflow vent.

10. The enclosure vent assembly of claim 1, wherein the vent is a relief valve.

11-20. (canceled)

21. A vent assembly comprising:
a vent body defining a vent cavity, a first axial end, a second axial end, circumferential threads positioned towards the second axial end, a sealing surface surrounding the vent cavity and facing the second axial end, and an annular pocket about the vent cavity having a depth in the axial direction; and
a vent disposed in the vent body, wherein the vent extends across the vent cavity.

22. The vent assembly of claim 21, wherein the vent comprises a PTFE membrane.

23. The vent assembly of claim 21, wherein the vent is a passive airflow vent.

24. The vent assembly of claim 23, further comprising a relief valve in parallel with the passive airflow vent with respect to airflow through the vent body.

25. The vent assembly of claim 24, wherein the relief valve is an umbrella valve defining a vent opening and a vent mounting surface about the vent opening, and the passive airflow vent is coupled to the vent mounting surface across the vent opening.

26. The vent assembly of claim 25, wherein the passive airflow vent is recessed in the axial direction from an outer portion of the relief valve.

27. The vent assembly of claim 21, wherein the vent is a relief valve.

28. The vent assembly of claim 21, wherein the annular pocket is positioned radially between the circumferential threads and the sealing surface.

29. The vent assembly of claim 21, wherein the annular pocket extends axially from the sealing surface towards the first axial end.

30-31. (canceled)

32. The vent assembly of claim 21, further comprising a vent cover extending across the first axial end of the vent body.

33. The vent assembly of claim 32, the vent cover comprising a puncturing mechanism extending from the cover towards the vent.

34-45. (canceled)
